(19) United States
(12) Patent Application Publication
(10) Pub. No.: US 2006/0234400 A1
(43) Pub. Date: Oct. 19, 2006

(54) Method of judging quality of semiconductor epitaxial crystal wafer and wafer manufacturing method using the same

(75) Inventors: Masaaki Nakayama, Nara (JP); Tomoyuki Takada, Ibaraki (JP); Taketsugu Yamamoto, Ibaraki (JP)

Correspondence Address: BIRCH STEWART KOLASCH & BIRCH, PO BOX 747, FALLS CHURCH, VA, 22040-0747, US

(73) Assignee: Sumitomo Chemical Company, Limited, Tokyo (JP)

(21) Appl. No.: 10/546,289

(22) PCT Filed: Feb. 19, 2004
(86) PCT No.: PCT/JP04/01895

§ 371 Date: May 30, 2006

(30) Foreign Application Priority Data
Feb. 21, 2003 (JP) 2003-044716

(51) Int. Cl. H01L 21/66; H01L 21/44; G01R 31/26

(52) U.S. Cl. 438/14; 438/607

(57) ABSTRACT

In a method of determining the quality of a semiconductor epitaxial crystal wafer having a buffer structure portion comprised of epitaxial layers the semiconductor epitaxial crystal wafer (S) is irradiated with pulsed exciting light (5A) to modulate an internal electric field of the buffer structure portion, the electric transport properties deriving from the crystal quality of the buffer structure of the semiconductor epitaxial crystal wafer (S) are predicted based on a spectral difference in reflectance in reflection probe light (3B) from the semiconductor epitaxial crystal wafer (S), to determine the crystal quality of the buffer structure portion. The crystal quality may also be determined based on electric field strength calculated from Franz-Keldysh oscillation originating in the semiconductor chemical compound of the buffer structure portion.

### TECHNICAL FIELD

The present invention relates to a method of determining quality of semiconductor epitaxial crystal wafer that enables the quality of semiconductor epitaxial crystal wafer used for fabricating various types of semiconductor device to be determined non-destructively, and to a wafer manufacturing method using same.

### BACKGROUND ART

In semiconductor epitaxial crystal wafers having a field effect transistor type structure used when fabricating semiconductor devices such as field effect transistors (FET) and the like, generally, in order to avoid the effect defects and the impurity level originating in the substrate prior to stacking on the prepared substrate the various types of semiconductor epitaxial crystal layers needed to achieve the required functions, an epitaxially grown buffer structure portion is formed on the substrate.

After pre-treating the substrate surface, the buffer structure portion formed on the substrate prepared for that purpose is formed by molecular beam epitaxial growth, metal-organic chemical vapor phase epitaxial growth, hydride vapor phase epitaxial growth or other such epitaxial crystal growth. The quality of the buffer structure portion thus formed has a major effect on the electrical transport properties of the completed semiconductor device such as pinch-off characteristics and threshold voltage and the like. That is, a crystal quality of the buffer structure portion that is insufficient degrades the electrical insulation performance of the buffer layer, causing the occurrence of electrical defects, such as faulty pinch-off, in the fabricated semiconductor device, and in addition results in faulty characteristics such as the semiconductor device characteristics not matching the design specifications.

Therefore, in the process of manufacturing a semiconductor epitaxial crystal wafer, it is desirable to endeavor to improve the yield by determining the quality of the buffer structure portion and manufacturing semiconductor devices using only wafers having the required level of quality. Conventionally, determining the quality of the buffer structure portion for that purpose was carried out by following the processing of the semiconductor device, with respect to the wafer, by directly connecting an electrical measurement system, running an actual electric current to the wafer and measuring the electric current value. With this conventional method, therefore, it is necessary to destroy the semiconductor epitaxial crystal wafer in order to determine the wafer quality. As such, the above-described conventional method has the problem that testing requires a great amount of time and work, so it is impossible to perform the testing in a short time, and the yield is unavoidably reduced by the destruction of the wafer.

Employing an assessment method that uses an optical technique can be thought of as superior from the point of being non-destructive. As an optical technique in such a case, conventionally known reflection or transmission spectrometry, also emission spectrometry, have been generally employed in this field as methods of non-destructively examining the electron energy structure of semiconductor epitaxial crystal. However, in the case of semiconductor epitaxial crystal having a multilayer structure, in the spectrum obtained by ordinary reflection or transmission spectrometry, there are observed beats due to Fabry-Perot interference, with the electron energy level often being hidden in that interference. Even in the case, also, of a spectrum obtained by the emission spectrometry method, it can be difficult to tell whether the emission is an emission from an object energy level or emissions from impurity levels or the like. As such, it is impossible to make an assessment with respect to an internal electric field produced in a semiconductor epitaxial crystal, using the usual reflection or transmission spectrometry, or emission spectrometry.

Thus, previously there has not existed a quality assessment method that can non-destructively determine the quality of semiconductor epitaxial crystal wafers used in the manufacture of field effect transistors (FET) and readily enable selection of those suitable for fabricating semiconductor devices having excellent electrical characteristics. Previously, therefore, in the process of manufacturing a semiconductor epitaxial crystal wafer, the quality assessment process has required much time and work, and given rise to loss caused by destruction for testing, which has been a cause of increased costs. Moreover, since it has not been possible to carry out adequate quality assessment, the final product yield has not been satisfactory, and further improvement in the variation in quality of the manufactured semiconductor epitaxial crystal wafers is desired.

An object of the present invention is to provide a method of determining the quality of a semiconductor epitaxial crystal wafer that makes it possible to resolve the above-mentioned problems in the conventional technology.

Another object of the present invention is to provide a method of determining the quality of semiconductor epitaxial crystal that can non-destructively assess, in a short time, the quality of semiconductor epitaxial crystal wafers having a buffer structure, particularly the crystal quality of the wafer buffer structure portion, and readily enable selection of those suitable for fabricating semiconductor devices having excellent electrical characteristics.

Another object of the present invention is to provide a method of manufacturing an improved semiconductor epitaxial crystal wafer.

Yet another object of the present invention is to provide a high-quality semiconductor epitaxial crystal wafer.

### DISCLOSURE OF THE INVENTION

To resolve the above-mentioned problems, the present inventors carried out various studies of a method for non-destructively obtaining data relating to wafer quality, particularly the crystal quality of a buffer structure portion formed on a substrate. The surprising result was that the present inventors discovered that there is a correlation between a spectrum obtained by the photoreflectance method, and electrical transport properties of the field effect transistor fabricated using the epitaxial wafer such as the pinch-off characteristics and the threshold voltage and the like, and as the outcome of various studies repeated over and over again, accomplished the present invention.

The present invention makes it possible to do what has been hitherto difficult, non-destructively determine the quality of electrical transport properties that derive from the crystal quality of the buffer structure portion, from a spectrum obtained by the photoreflectance method, making it possible to readily select semiconductor epitaxial crystal wafers suitable for fabricating semiconductor devices having excellent electrical characteristics.

The photoreflectance method utilized by the present invention is a kind of modulation spectroscopy. Modulation spectroscopy is a method of detecting, with good sensitivity, the modulation components of reflected light or transmitted light produced as a result of applying a periodic external perturbation (electric field, magnetic field, pressure, temperature, etc.) to a specimen such as a semiconductor device or the like, modulating band structures in the specimen in synch with the external perturbation. This modulation spectroscopy method enables internal electric fields to be measured with high sensitivity. With the photoreflectance method, exciting light is used as the periodic external perturbation and the changes in the band structure modulated by the exciting light is extracted by reflection, obtaining a photoreflectance spectrum (hereinbelow abbreviated to PR spectrum). Generally, an oscillation structure dependent on the internal electric field of the specimen is observed in the PR spectrum. This oscillation structure is called Franz-Keldysh oscillation (hereinbelow abbreviated to FK oscillation) from an electro-optical effect. The present invention determines the quality of a semiconductor epitaxial crystal wafer based on the PR spectrum and/or the FK oscillation and/or the like.

Pinch-off characteristics, threshold voltage, drain-source current and the like are examples of the transistor characteristics of field effect transistors that are electric transport properties deriving from the crystal quality of the buffer structure portion of the semiconductor epitaxial crystal wafer. The determination method of the present invention is particularly suitable for determining the quality of characteristics relating to pinch-off characteristics and threshold voltage.

Factors affecting the crystal quality of the buffer structure portion include residual impurity concentration, crystal defect density, dislocation defect density, and residual impurities in the interface between substrate and epitaxial layer. Because any of these can impart a change to the energy band structure of the buffer structure portion, they can be considered to have an effect on the electric transport properties of the semiconductor device.

In utilizing PR spectra to determine the quality of a semiconductor epitaxial crystal wafer, a semiconductor epitaxial crystal wafer that has a critical electric transport property is selected beforehand and the PR spectrum of that wafer is compared to the spectrum of the wafer to be determined in order to determine the quality. Here, the PR spectrum of the semiconductor epitaxial crystal wafer having a critical property may be one that is actually measured or one obtained by numerical simulation.

Methods of comparing PR spectra that may be cited include, for example, methods that compare the shape of PR spectra, electric field intensities calculated from FK oscillations in the PR spectra, spectra obtained by Fourier transformation of FK oscillations, and electric field intensities calculated by Fourier transformation of FK oscillations.

In this way, it is possible to determine wafer quality, non-destructively and quickly, by non-destructively measuring the PR spectrum of the semiconductor epitaxial crystal wafer to be determined and comparing it with the PR spectrum obtained from a semiconductor epitaxial crystal wafer having an electric transport property critical characteristic that is selected beforehand. And, if this determination method is used to manufacture semiconductor epitaxial crystal wafers, it greatly reduces the time and work of the quality assessment process in the semiconductor epitaxial crystal wafer manufacturing process, and does not give rise to loss caused by destruction for testing, enabling costs to be greatly reduced. Moreover, adequate quality assessment can be carried out, so final product yield is improved and variation in the quality of the manufactured semiconductor epitaxial crystal wafers is reduced.

In a method of determining the quality of a semiconductor epitaxial crystal wafer having a buffer structure portion comprised of epitaxial layers and having a field effect transistor type structure, the present invention is characterized in that the semiconductor epitaxial crystal wafer is irradiated with exciting light to modulate an internal electric field of the buffer structure portion, and the electric transport properties of a field effect transistor fabricated using the semiconductor epitaxial crystal wafer are predicted based on a PR spectrum from the semiconductor epitaxial crystal wafer.

Said prediction of the electric transport properties may also be made by comparing a PR spectrum obtained from a semiconductor epitaxial crystal wafer having a critical electric transport property with the PR spectrum from the above semiconductor epitaxial crystal wafer.

The comparison can be carried out using at least one selected from among shapes of PR spectra, electric field intensities calculated from FK oscillations in spectra shapes of spectra obtained by Fourier transformation of FK oscillations, and electric field strengths calculated by Fourier transformation of FK oscillations.

In a method of manufacturing a semiconductor epitaxial crystal wafer, the present invention is also characterized by including a step of obtaining, by an epitaxial growth method, a semiconductor epitaxial crystal wafer having a buffer structure portion comprised of epitaxial layers and having a field effect transistor type structure, and a step of irradiating the semiconductor epitaxial crystal wafer with exciting light to modulate an internal electric field of the buffer structure portion and, based on a PR spectrum from the semiconductor epitaxial crystal wafer, determining the quality of the semiconductor epitaxial crystal wafer.

The present invention is also characterized by semiconductor epitaxial crystal wafers manufactured using the above manufacturing method.

### BRIEF DESCRIPTION OF DRAWINGS

FIG. 1 is a block diagram showing the configuration of a determination apparatus used for the determination of semiconductor crystal according to the method of the present invention.

FIG. 2 is a diagram showing PR spectra measured by the apparatus shown in FIG. 1.

FIG. 3 is a diagram showing spectra obtained by Fourier transformation of FK oscillations of PR spectra.

FIG. 4 is an process explanatory diagram for explaining an example of the process of manufacturing a semiconductor epitaxial crystal wafer according to the present invention.

### BEST MODE FOR CARRYING OUT THE INVENTION

The present invention will now be described in further detail, with reference to the accompanying drawings.

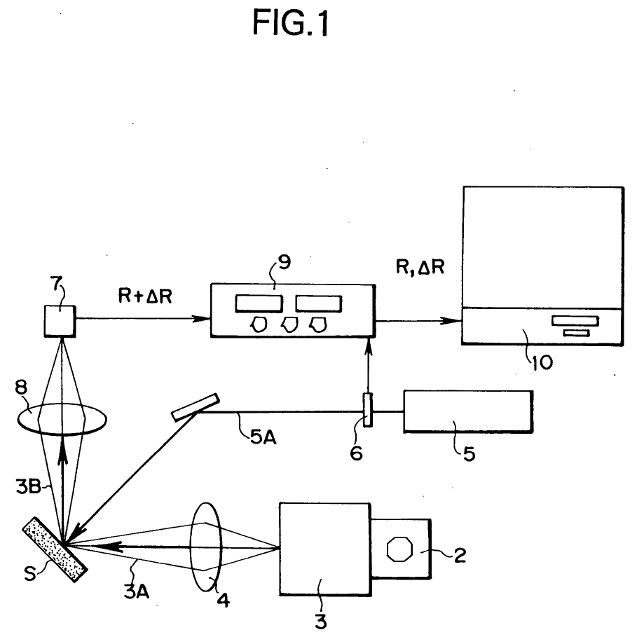

FIG. 1 is a block diagram showing the configuration of a measurement apparatus used for the determination of semiconductor crystal according to the method of the present invention. Measurement apparatus 1 is an apparatus configured to be able to obtain data for assessing and determining the quality of the electric transport properties of a semiconductor epitaxial crystal wafer by using the photoreflectance method to measure the PR spectrum of the semiconductor epitaxial crystal wafer. The measurement apparatus 1 is configured by an optical system for laser light that is modulation light added to an optical system for measurement by the usual reflection spectroscopy. In the additional optical system, the laser light is modulated by a chopper, for example, and the modulated laser light irradiates the semiconductor epitaxial crystal wafer specimen. The method uses a lock-in detector to detect the difference in reflected light intensity (DR) between when being irradiated by the laser light and when not being irradiated, or the difference in reflected light intensity (DR) between when the laser light irradiation intensity is strong and when it is weak.

The wafer S constituting the measurement specimen in the example of FIG. 1 is a semiconductor epitaxial crystal wafer used to fabricate a field effect transistor (FET). The wafer S is constituted by forming, on a GaAs substrate, a buffer layer that includes an i-GaAs layer and an AlGaAs layer, on which is formed an InGaAs-layer single quantum well layer structure between modulation doped AlGaAs layers, and, further, an n-GaAs layer that is a cap layer is formed thereon.

When the field effect transistor (FET) using the wafer S having the above configuration is fabricated, for some reason or another in the wafer S growth process, there arise cases in which the pinch-off characteristics are good and cases in which that is not so. A wafer with good pinch-off characteristics is termed the OK wafer, and one with faulty pinch-off characteristics is termed the NG wafer. This NG wafer is a semiconductor epitaxial crystal wafer having an electric transport property limit characteristic that forms the standard for determining the semiconductor epitaxial crystal wafer quality.

The measurement apparatus 1 has a white light source 2; light from the white light source 2 is separated by a spectroscope 3, forming probe light 3A. The probe light 3A is converged by lens 4 and irradiates a desired observation spot on the specimen wafer S.

Laser light from a laser light source 5 is pulsed by a modulation chopper 6 to form pulsed exciting light 5A. The pulsed exciting light 5A irradiates the wafer S, whereby reflection probe light 3B from the wafer S, derived from the probe light 3A, is modulated by the pulsed exciting light 5A.

The configuration constitutes one in which reflection probe light 3B thus modulated is collimated by lens 8 and is input to a photodetector 7, and from the photodetector 7, detection voltages R+ΔR are input to a lock-in amp 9.

A modulation signal from the chopper 6 is input to the lock-in amp 9 as a synchronization reference signal, and of the detection voltages R+ΔR, from the lock-in amp 9, a signal corresponding to reflectance R of the probe light 3A is output as reference signal R, and a signal corresponding to the probe light reflectance modulation component ΔR modulated by the pulsed exciting light 5A is output as output signal ΔR. The output signal ΔR and reference signal R are input to a computer 10.

Based on the output signal ΔR and the reference signal R, the computer 10 calculates the small change ratio ΔR/R in reflectance caused by the exciting light. Usually, the ΔR/R spectrum with respect to light wavelength or light energy is termed PR spectrum. Also, those that are graphed after appropriate numerical processing of wavelength and of ΔR/R can also be thought of as PR spectra. It is known that in these PR spectra, oscillation called FK oscillation appear on the side where the energy is higher than the semiconductor bandgap energy. The intensity of the internal electric field in the buffer structure portion of the wafer S is calculated from the peak position periods of the FK oscillation waveforms.

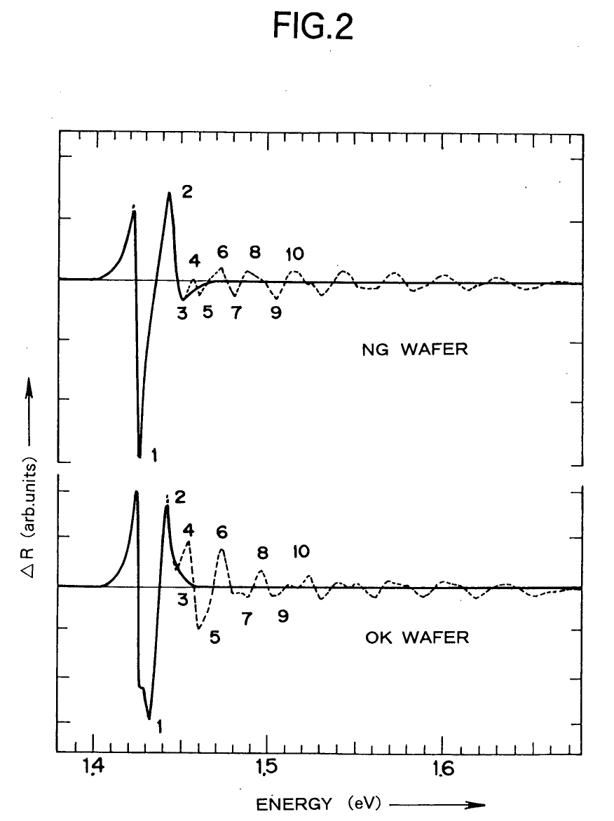

Next, the processing of the determination of the quality of the wafer S, based on PR spectra, will be specifically explained, with reference to FIG. 2. FIG. 2 shows an example of a PR spectrum of an OK wafer and of a NG wafer measured at room temperature. The energy of a component having a large amplitude observed in the vicinity of 1.43 eV is considered to correspond to the bandgap energy from GaAs contained in the buffer structure portion. Oscillation called FK oscillation is clearly observed on the side where the energy is higher than this bandgap energy. Here, from the waveform of the FK oscillation appearing in the PR spectrum, it can be clearly understood that the OK wafer and NG wafer have different peak position periods. From this, it is clear that the OK wafer and NG wafer can be clearly differentiated from the peak position periods in the FK oscillation waveforms. Therefore, it is clear that the quality of the electric transport properties of semiconductor epitaxial crystal wafers can be determined from a comparison of the PR spectra.

Next, in order to investigate the internal electric fields generated inside the wafer S having this epitaxial crystal structure, electric field intensity F was calculated from the observed FK oscillation described above. This FK oscillation has the form of the following equation

$$\frac{Δ R}{R} ∝ cos \{ {( 2 / 3 ) [ ( En - {E}_{0} ) / ℏΩ ]}^{3 / 2} + π ( d - 1 ) / 2 \} , {( ℏΩ )}^{3} = {( eF ℏ )}^{2} / 8 μ \qquad ( 1 )$$

Here, n is oscillation order in the oscillation structure, En is the energy of the nth oscillation, E0 is electron transition energy, F is internal electric field intensity, i is electron-hole reduced mass of transition, d is a dimensionality dependent value, h is Planck constant, e is elementary electric charge, and Ω is electro-optical energy. From this equation (1), the electric field strength F produced in the specimen can be calculated by plotting En−E0 of the FK oscillation observed in the PR spectrum as an oscillation order function. The solid lines in FIG. 2 show the result of a simulation derived from equation (1), obtained using a calculated electric field strength F.

Here, in FIG. 2 an index is affixed to the respective FK oscillation peaks of the OK wafer and NG wafer. The index is plotted using index related values (n) along the horizontal axis, and indexed oscillation peak energy along the vertical axis. From the slope thereof, it is possible to calculate that the internal electric field strength of the OK wafer is 6.5 kV/cm, and that the internal electric field strength of the NG wafer is 10 kV/cm. That is, adopting a method that utilizes electric field strength calculated from the FK oscillation of PR spectra clearly makes it possible to determine the quality of the electric transport properties of a semiconductor epitaxial crystal wafer.

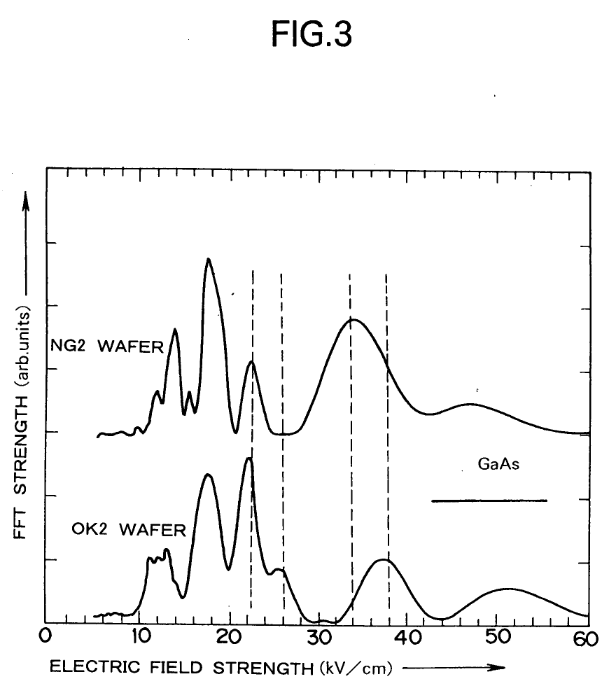

Next, the processing of the determination of the quality of the wafer S, based on Fourier analysis of FK oscillation observed in PR spectra, will be specifically explained, with reference to FIG. 3. Here, the PR spectrum was measured using as the specimen a semiconductor epitaxial crystal wafer S2 (hereinbelow called wafer S2) having a different buffer structure to that of the above wafer S. Similarly to the foregoing, a wafer with good pinch-off characteristics is termed the OK2 wafer, and one with faulty pinch-off characteristics is termed the NG2 wafer.

As in the above, equation (1) expresses the FK oscillation observed in the PR spectrum. In this equation, if τ≡(En−E0)3/2, η≡(2/3) (1/hθ)3/2), equation (1) can be modified as follows.

$$\frac{Δ R}{R} ∝ cos ( η τ + ϕ ) \qquad ( 2 )$$

Here, θ is a dimensionality dependent term. This is an oscillation function (trigonometric function) relating to τ with η−1 as period, indicating that the value of η can be obtained by Fourier transformation of the FK oscillation. The wafer measured this time can be thought of as a wafer in which the electric field distributes in the depth direction. Even in cases in which the internal electric field changes with respect to locations in the depth direction, FK oscillations from regions produced by each electric field are regarded as being independently observed, and as expressed by superimposition of equation (1). That is, even in cases in which the electric field strength distributes in the depth direction of wafer S2, it is regarded as being expressed by the following equation.

$$\frac{Δ R}{R} ∝ {\sum }_{j} {A}_{j} cos ( {η}_{j} τ + {ϕ}_{j} ) \qquad ( 3 )$$

The subscript j represents the jth FK oscillation, expressed by superimposition. Spectrum ψ(η) in respect of η is obtained by Fourier transformation of the above equation.

$$Ψ ( η ) ∝ \int {\sum }_{j} {A}_{j} cos ( {η}_{j} τ + {ϕ}_{j} ) exp ( - ⅈη τ ) ⅆ τ \qquad ( 4 )$$

In this equation, the electric field distribution of wafer S2 can be obtained by Fourier transformation after changing the PR spectrum horizontal axis to function τ, and reading the value of η in the peak observed in the obtained spectrum.

FIG. 3 is the FK oscillation observed in the PR spectrum in the specimen measured this time and Fourier transformed with the electric field strength plotted along the horizontal axis. The electric field distribution indicates the electric field intensity of regions containing GaAs layers, showing the complex structure. A comparison of the OK2 wafer and NG2 wafer shows points where the internal electric field distribution coincides mixed with points where it does not coincide. For example, in the Fourier transformed spectra, it is observed that the peak is at about 37 kV/cm in the OK2 wafer and at about 33 kV/cm in the NG2 wafer. This can be considered as showing that the internal electric field intensity produced in the NG2 wafer is smaller compared to the internal electric field intensity produced in the OK2 wafer.

Clearly, therefore, it is possible to determine the quality of the electric transport properties of a semiconductor epitaxial crystal wafer by utilizing the internal electric field strength calculated from spectra obtained by Fourier transformation of FK oscillation.

Moreover, in an internal electric field of about 26 kV/cm, a peak can be observed in a Fourier transformed spectrum in the OK2 wafer, but that peak does not appear in the NG2 wafer. Thus, clearly it is possible to determine the quality of the electric transport properties of a semiconductor epitaxial crystal wafer by utilizing the shape of a spectrum obtained by Fourier transformation of FK oscillation.

As described in the foregoing, the crystal quality of the buffer structure portion of a semiconductor epitaxial crystal wafer having a buffer structure can be non-destructively assessed in a short time, and it is also possible to readily select a semiconductor epitaxial crystal wafer suitable for fabricating semiconductor devices with excellent electrical characteristics, enabling manufacturing efficiently and yield to be greatly improved.

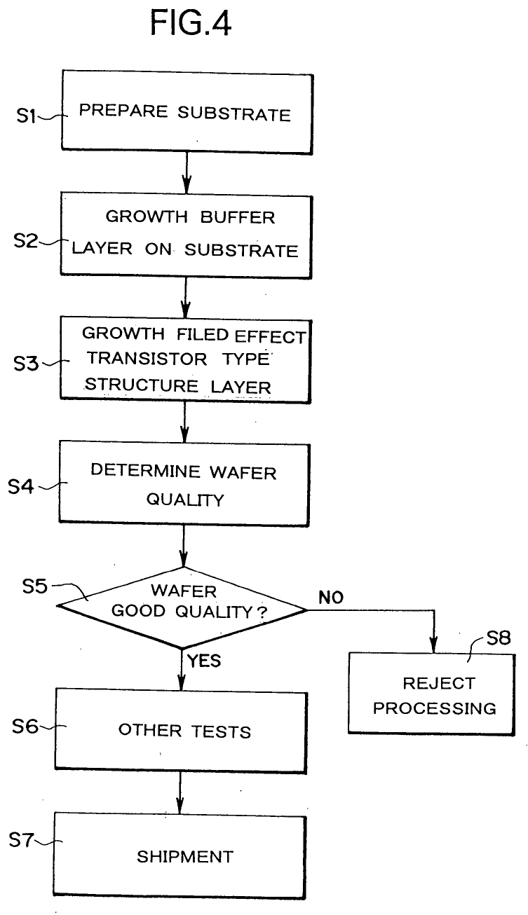

FIG. 4 is an process explanatory diagram for explaining an example of the method of manufacturing a semiconductor epitaxial crystal wafer according to the present invention. The manufacturing method will now be explained with reference to FIG. 4. First, in step S1, a GaAs substrate is prepared. Next, in step S2, a buffer layer is formed on the GaAs substrate. This buffer layer structure includes a GaAs layer or AlGaAs layer. In step S3, a field effect transistor type structure layer is formed on the buffer layer formed in step S2. This field effect type transistor structure layer forms an InGaAs-layer single quantum well layer structure between modulation doped AlGaAs layers, and, further, has an n-GaAs layer that is a cap layer, formed thereon. However, the constitution of the buffer layer and field effect transistor type structure layer is not limited to this example, and may be formed as a known appropriate layer structure. It is also possible to use a known appropriate method as the layer forming method.

When, thereby, a semiconductor epitaxial crystal wafer is obtained that has a buffer structure portion comprised of epitaxial layers and a field effect transistor type structure, in step S4, the quality of the wafer is determined. This quality determination is carried out using the measurement apparatus 1 shown in FIG. 1, by the procedure already described. That is, the quality of the semiconductor epitaxial crystal wafer is determined by predicting the electric transport properties of the field effect transistor fabricated using the semiconductor epitaxial crystal wafer, based on the PR spectrum from the semiconductor epitaxial crystal wafer. With respect to the determination method, any one of the number of methods described in the foregoing may be used.

That is, the electric transport properties may be predicted by comparing a PR spectrum obtained from a semiconductor epitaxial crystal wafer that has a critical electric transport property with a PR spectrum from a semiconductor epitaxial crystal wafer prepared as a specimen.

The comparison can also be carried out using at least one selected from among the shape of PR spectra, electric field strengths calculated from FK oscillations' spectra obtained by Fourier transformation of FK oscillations, and electric field strengths calculated by Fourier transformation of FK oscillations.

In step S5, it is determined whether or not the wafer was determined to be of good quality in step S4. If the wafer was determined to be of good quality, the determination result in step S5 is YES, and the process advances to step S6, where other tests of the wafer are conducted, and a wafer that passes those tests is shipped as a product (step S7).

If in step S5 a wafer is determined to be faulty, the determination result in step S5 is NO, and the process advances to step S8, where the wafer is rated as a reject and not shipped.

### INDUSTRIAL APPLICABILITY

As described in the foregoing, with the method of determining the quality of a semiconductor epitaxial crystal wafer and the wafer manufacturing method using same according to the present invention, wafer crystal quality can be non-destructively assessed in a short time, making it readily possible to select wafers suitable for fabricating semiconductor devices having excellent electrical characteristics, and helping to reduce costs.

1. A method of determining the quality of a semiconductor epitaxial crystal wafer having a buffer structure portion comprised of epitaxial layers and having a field effect transistor type structure,
characterized in that the semiconductor epitaxial crystal wafer is irradiated with exciting light to modulate an internal electric field of the buffer structure portion, and
the electric transport properties of a field effect transistor fabricated using the semiconductor epitaxial crystal wafer are predicted based on a photoreflectance spectrum from the semiconductor epitaxial crystal wafer.

2. A method of determining the quality of a semiconductor epitaxial crystal wafer as described in claim 1, wherein said the electric transport properties is predicted by comparing a photoreflectance spectrum obtained from a semiconductor epitaxial crystal wafer having a critical electric transport property with the photoreflectance spectrum from the semiconductor epitaxial crystal wafer.

3. A method of determining the quality of a semiconductor epitaxial crystal wafer as described in claim 2, wherein said comparison is carried out using at least one selected from among shapes of photoreflectance spectra, electric field strengths calculated from Franz-Keldysh oscillations' shapes of spectra obtained by Fourier transformation of Franz-Keldysh oscillations, and electric field strengths calculated by Fourier transformation of Franz-Keldysh oscillations.

4. A semiconductor epitaxial crystal wafer manufacturing method, characterized by including
a step of manufacturing a semiconductor epitaxial crystal wafer having a buffer structure portion comprised of epitaxial layers and having a field effect transistor type structure by an epitaxial growth method, and
a step of determining quality of the semiconductor epitaxial crystal wafer using a method described in claim 1, 2 or 3.

5. A semiconductor epitaxial crystal wafer manufactured using the manufacturing method of claim 4.
